(19) United States
(12) Patent Application Publication
(10) Pub. No.: US 2026/0031130 A1
(43) Pub. Date: Jan. 29, 2026

(54) APPARATUSES AND METHODS FOR ACCESS COUNT UPDATE OPERATIONS ALONG A DIFFERENT WORD LINE

(71) Applicant: Micron Technology, Inc., Boise, ID (US)

(72) Inventor: Sujeet Ayyapureddi, Boise, ID (US)

(21) Appl. No.: 19/268,739

(22) Filed: Jul. 14, 2025

Related U.S. Application Data
(60) Provisional application No. 63/675,421, filed on Jul. 25, 2024.

(51) Int. Cl. G11C 11/406; G11C 11/408

(52) U.S. Cl. CPC G11C 11/40622; G11C 11/40615; G11C 11/4085; G11C 11/4087

(57) ABSTRACT

A memory has a bank with at least two row decoders each of which control a respective portion of the word lines of the bank. Each word line has an associated access count which is stored along a word line in the other portion. For example, if the memory receives an activate command and a row address that specifies a first word line in the first portion, then a second word line in the second portion is also activated and an access count along the second word line is read out and updated. Since the first and second word line are activated by separate row decoders, the access count update operation may be performed during an activation time tRAS.

### CROSS REFERENCE TO RELATED APPLICATION(S)

This application claims the benefit under 35 U.S.C. § 119 of the earlier filing date of U.S. Provisional Application Ser. No. 63/675,421 filed Jul. 25, 2024 the entire contents of which is hereby incorporated by reference in its entirety for any purpose.

### BACKGROUND

Information may be stored on memory cells of a memory device. The memory cells may be organized at the intersection of word lines (rows) and bit lines (columns). Information in the memory cells may decay over time. For example, the information may be stored as a charge on a capacitor which may decay over time. The memory device may perform refresh operations to restore the information and prevent information from being lost.

Certain patterns of access may cause an increased rate of information decay in nearby memory cells (e.g., the memory cells along nearby word lines). Memory devices may use various schemes to identify these access patterns so that additional targeted refresh operations may be performed. Memory devices may track accesses to different word lines in order to determine when targeted refresh operations are called for and where they should be performed. There may be a need to optimize the timing of adjusting the access counts.

### BRIEF DESCRIPTION OF THE DRAWINGS

FIG. 1 is a block diagram of a semiconductor device according to at least one embodiment of the disclosure.

FIG. 2 is a block diagram of bank logic circuits according to some examples of the present disclosure.

FIG. 3 is a schematic diagram of an example layout of a memory bank according to some embodiments of the present disclosure.

FIG. 4 is an example timing diagram of activation and ACU operations in a memory device according to some embodiments of the present disclosure.

FIG. 5 is an example timing diagram of activation and ACU operations with a column command according to some embodiments of the present disclosure.

FIG. 6 is a flow chart of a method of performing an ACU operation on a count value associated with a word line according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address. Selected memory cells along that active word line may have their information read from or written to based on which bit lines are selected by a column address. The word line is deactivated when it is pre-charged. The memory may have different timing specifications. For example, a time tRAS is the minimum time after an activation command before a pre-charge command can be received. A time tRCD specifies the minimum time after an activation command before a column command, such as a read or write, may be received. A time tRP is a minimum time after a pre-charge command before a next activation command can be received. Together these give a minimum activate to activate timing tRC.

Information in the memory cells decays over time. To prevent information loss, the memory array may be refreshed on a row by row basis (e.g., as part of an auto-refresh and/or self-refresh mode) where the memory cells along each row are refreshed periodically to restore the stored information to an initial value. Such refresh operations may be referred to as sequential refresh operations or normal refresh operations, as the memory may use some sequence logic (e.g., a counter) to generate refresh addresses used to determine which word lines are refreshed. The speed at which the rows are refreshed (e.g., the maximum time any given row will go between refreshes) may be determined based on an expected rate of information decay and may be adjusted based on various conditions of the memory (e.g., temperature).

Various patterns of access to a row (an aggressor row) may cause an increased rate of information decay in nearby memory cells (e.g., along victim rows). For example, a ‘row hammer’ may involve repeated accesses to the aggressor row which may increase a rate of decay in adjacent rows (and/or in rows which are further away). Accordingly, it may be important to track a number of accesses to each row to determine if they are aggressors, such that the victim rows can be identified and refreshed as part of a targeted refresh operation. For example, per-row access counts (PRAC) may be used where each word line may have an associated access count value which is used to determine how many times that word line has been accessed. The access counts may be used to determine if the row is an aggressor, for example if the access count crosses a threshold.

When a word line is accessed, an access count update (ACU) operation is performed where the access count associated with that word line is read out, modified (e.g., incremented), and then the updated access count is written back. This may affect the timing of operations, since a read-modify-write (RMW) is performed on the access count. In a conventional memory device the access counts may share a read path with the word line being accessed. Accordingly, the ACU operation may be performed when the pre-charge command is received, indicating that no more column commands are being performed on that word line, so that the ACU operation doesn't interfere. This may lead to a shortened tRAS timing and an increased tRP timing. However, the shortened tRAS timing may prevent column commands from being performed without causing extensions of tRP. Since this decreases the performance of the memory, it may be useful to find ways to perform ACU operations while allowing a tRAS duration that allows for column commands without an extended timing.

The present disclosure is drawn to apparatuses, systems, and methods for access count update operations along a different word line. The memory array includes a first row decoder and a second row decoder. The access counts for the word lines coupled to the first row decoder are stored along word lines coupled to the second row decoder. Since the access count does not share a read path with the associated word line, the ACU operation may be performed during tRAS rather than during tRP. This may allow tRAS to be longer than tRP. However, since tRAS is extended, one or more column commands may be performed during tRAS without causing an extension of the overall tRC timing.

In an example implementation, the memory device may receive a row activation command at a first time and a row address as part of an access operation. A first row decoder may activate a first word line and a second row decoder activates a second word line responsive to the row activation command and the row address. The access count is stored along the second word line, and an ACU operation is performed on the access count along the second word line. At a second time after the first time, a pre-charge command is received. Responsive to this, the first row decoder pre-charges the first word line and the second row decoder pre-charges the second word line. Between the first time and the second time, the memory may receive one or more column commands for the first word line.

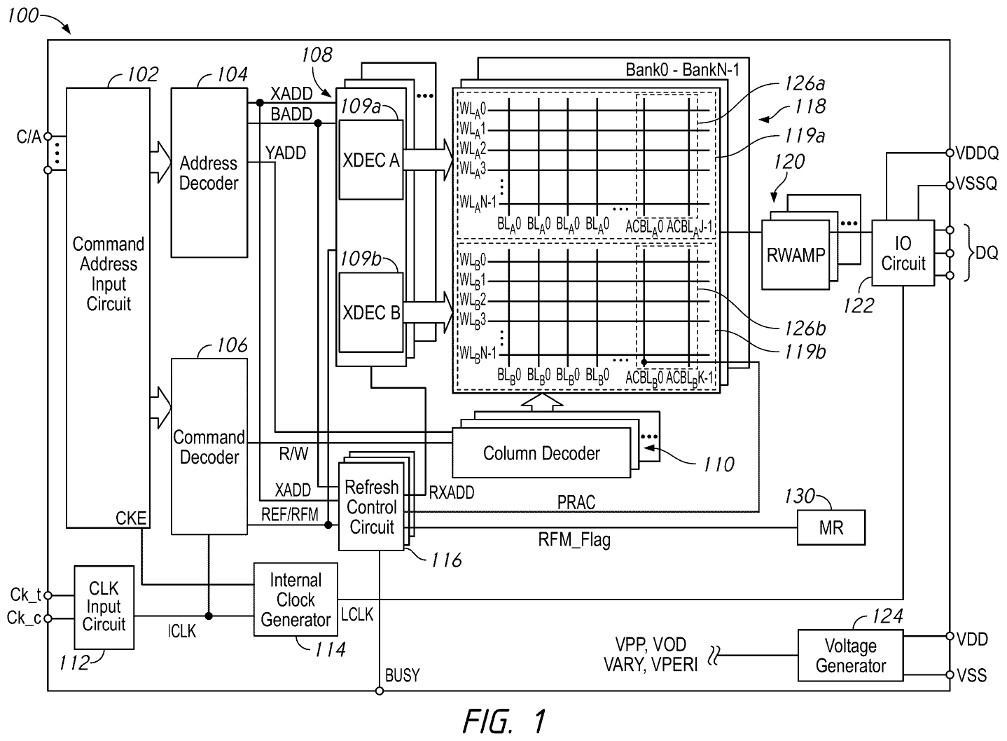

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a host or controller (not shown). The controller may be any device (or collection of devices) which stores information on the memory. For example, the controller may be a processor. In some embodiments, the controller and memory 100 may be packaged together on a single integrated circuit. In some embodiments, the controller and memory 100 may be separate. In some embodiments, the controller may operate multiple memory devices 100.

The semiconductor device 100 includes a memory array 118. The memory array 118 may organized into one or more memory banks. In the embodiment of FIG. 1, the memory array 118 is shown as including N memory banks BANK0-BANKN−1. For example there may be 2, 4, 8, or 16 memory banks. More or fewer banks may be included in the memory array 218 of other embodiments. Each memory bank includes a plurality of word lines WL (rows), a plurality of bit lines BL (columns), and a plurality of memory cells arranged at intersections of the plurality of word lines WL and the plurality of bit lines BL. Each bank is associated with a value of a bank address BADD.

The selection of the word line WL is performed by bank row decoders 108 and the selection of the bit lines BL is performed by a column decoder 110. Certain circuits, such as the bank row decoders 108 and the column decoder 110 are repeated on a bank-by-bank basis. For example, if there are N banks there may be N bank row decoders 108 and N column decoders 110. Certain other circuits of the memory device 100 may also be repeated on a bank-by-bank basis. For example, each bank may have an associated bank logic region which includes the circuits associated with that bank.

The bit lines BL are coupled to a respective sense amplifier (SAMP). The sense amplifiers are coupled to local input/output (LIO) and global input/output (GIO) to read/write amplifiers (RWAMP) 120 and through those to the input/output circuits 122 of the memory device 100. During an access operation, the bank row decoder circuits 108 activate a word line specified by the row address. The activated word line couples the memory cells along that word line to the intersecting bit lines. During a read operation, the sense amplifiers amplify the signal along that bit line to a voltage that represents the logical level stored in the memory cell. During a write operation, the sense amplifiers receive a signal indicating a logical level to be written and amplify it onto the bit line and through the bit line to the memory cell. After operations, the bank row decoder circuits 108 pre-charge the word line.

The banks may be divided into one or more portions 119, each of which is associated with a respective row decoder 109. For example, FIG. 1 shows two portions 119a and 119b, each with their own respective set of word lines WL_{A} and WL_{B} and their own respective set of bit lines BL_{A} and BL_{B}. The different portions may have a same or different number of word lines, bit lines, or combinations thereof. The bank row decoder circuits 108 for that bank include two row decoders 109a and 109b. The row decoder 109a is associated with the first portion 119a and the row decoder 109b is associated with the second portion 119b. One or more bits of the row address XADD may specify which portion to perform the access operation in. More portions per bank may be used in other example embodiments.

The semiconductor device 100 may employ a plurality of external terminals coupled to the controller. The external terminals include command and address (C/A) terminals coupled to the controller along a command and address bus to receive commands and addresses. Other external terminals include clock terminals to receive clocks clock signals CK and /CK along a clock bus, data terminals DQ to send and receive data along a data bus, and power supply terminals to receive power supply potentials such as VDD, VSS, VDDQ, and VSSQ.

The clock terminals are supplied by the controller with external clocks CK and /CK that are provided to an input circuit 112. The external clocks may be complementary. The input circuit 112 generates an internal clock ICLK based on the CK and /CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses by the controller. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include access commands such as a row activation command ACT, one or more column commands such as read or write, and pre-charge command PRE, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations.

As part of an example write operation, the C/A terminals receive a row activation command ACT and a row address. The row address includes one or more bits which specify which portion 109 to activate. The selected row decoder 109 activates the specified word line. As explained in more detail herein, the non-selected row decoder 109 activates an associated word line in the non-selected portion and an ACU operation is performed on a count value in the non-selected portion responsive to the ACT command. The C/A terminals receive a column command, in this case write, along with a column address. The column decoder couples bit lines specified by the column address YADD to the LIO and GIO lines. The input/output circuit receives data along the data terminals DQ. The data is provided through the RWAMP 120 through the LIO and GIO lines to the specified bit lines. When the controller is done performing operations on the word line, the memory device 100 receives a pre-charge command PRE, and the active word lines are pre-charged.

As part of an example read operation, the C/A terminals receive a row activation command ACT and a row address. The row address includes one or more bits which specify which portion 109 to activate. The selected row decoder 109 activates the specified word line. As explained in more detail herein, the non-selected row decoder 109 activates an associated word line in the non-selected portion and an ACU operation is performed on a count value in the non-selected portion responsive to the ACT command. The C/A terminals receive a column command, in this case read, along with a column address. The column decoder couples bit lines specified by the column address YADD to the LIO and GIO lines. The sense amplifiers amplify the signal from the intersecting memory cells along the bit lines to the LIO and GIO lines through the RWAMP 120 to the IO circuit 122. The IO circuit 122 provides the read data to the data terminals DQ. When the controller is done performing operations on the word line, the memory device 100 receives a pre-charge command PRE, and the active word lines are pre-charged.

The device 100 may also receive commands causing it to carry out refresh operations. For example, the controller may issue a refresh command REF or a refresh management command RFM. Responsive to either the REF command or the RFM command, the refresh control circuit 116 may perform one or more refresh operations. As part of a refresh operation, the refresh control circuit 116 issues a refresh address RXADD, and the bank row decoder circuits 108 may refresh one or more word lines based on the refresh address RXADD. The number and type of refresh operations performed may vary based on whether REF or RFM is received. In some embodiments, the refresh control circuit 216 may be repeated on a bank-by-bank basis, similar to the row decoder 108 and column decoder 110.

The refresh commands REF and RFM are supplied to the refresh control circuit 116. The refresh address control circuit 116 supplies one or more refresh addresses RXADD to the row decoder 208, which refreshes one or more wordlines WL identified by the refresh row address RXADD. For example, in some embodiments, the refresh control circuit 116 may perform a mix of normal (or sequential) refresh operations and targeted refresh operations responsive to the refresh command REF, and may perform targeted refresh operations responsive to the RFM command RFM. In some embodiments, the refresh control circuit 216 may perform normal refresh operations responsive to REF and targeted refresh commands responsive to RFM.

The refresh control circuit 116 may perform a sequential refresh operation, or normal refresh operation, by issuing one or more sequential refresh addresses as RXADD. The sequential refresh addresses may be generated based on a sequence of addresses. For example, after issuing a sequential refresh address, a counter circuit may increment the address to generate the next address in the sequence (e.g., RXADD(i)=RXADD(i−1)+1). The refresh address control circuit 116 may cycle through the sequence of sequential addresses at a rate determined by REF. In some embodiments, the sequence of sequential addresses may include all the addresses in the memory bank 118. In some embodiments, the controller may issue the signal REF with a frequency such that most or all of the addresses in the memory bank 118 are refreshed within a certain period (e.g., such that there is a maximum specified time between two consecutive sequential refreshes of a given word line), which may be based on an expected rate at which information in the memory cells MC decays.

The refresh control circuit 116 may perform a targeted refresh operation for example, responsive to an RFM command. The refresh control circuit 116 identifies addresses as targets for targeted refresh operations. These addresses may generally be referred to as aggressors, although different embodiments may use different criteria for identifying these addresses. The refresh control circuit 116 may include a register which stores identified aggressors. As part of a targeted refresh operation, one or more refresh addresses are generated based on a selected aggressor. For example, in some embodiments, the refresh addresses may represent word lines which are physically adjacent to the word line associated with the identified aggressor address (e.g., RXADD=XADD+/−1). Other relationships may be used in other example embodiments. For example word lines which are further away (e.g., RXADD=XADD+/−2, +/−3, etc.) may be refreshed.

The memory device 100 uses per row activity counts (PRAC) to determine which rows are aggressors. In the example embodiment of FIG. 1, some of the memory cells of the array 118 may be set aside to store access counts. The memory cells 126 which are set aside for such a purpose may generally be referred to as counter memory cells 126. The counter memory cells 126 may store access count values PRAC, each of which is associated with one of the word lines. The count value PRAC may be stored as a binary number, with each bit stored in a memory cell along the word line. The counter memory cells are stored in memory cells along access count bit lines ACBL. The number of counter memory cells along each word line may be based on a number of bits of the count value PRAC.

In some embodiments, the counter memory cells 126 and access count bit lines may be referred to as such due to their use (storing the count values) and in some embodiments may be structurally similar to, or identical to, the other memory cells and bit lines of the array. In some embodiments, the counter memory cells 126 may be grouped together (e.g., at the end of the word line). Other distributions of the counter memory cells 126 along the word line may be used in other example embodiments. In some embodiments, the counter memory cells 126 may not be directly accessible by external devices such as controllers (e.g., to prevent the count values from being overwritten). In other words, the access count bit lines ACBL associated with the counter memory cells 126 may not be accessed by a normal column address.

The count values PRAC may be used to determine if the associated word line is an aggressor or not. For example, each time the word line is activated, a count value PRAC associated with that row is updated as part of an ACU operation. As part of an ACU operation, the count value PRAC associated with the row specified by XADD is read out to the refresh control circuit 116 and the refresh control circuit 116 updates the count, compares the updated count to a threshold and writes the updated count back to the counter memory cells 126. For example the count may be updated by being incremented as part of the ACU operation. If the updated count crosses the threshold, then the row address XADD may be stored as an aggressor and the count value may be updated by being reset to an initial value (e.g., 0). In some embodiments, the threshold may represent a maximum value of the count and the count may cross the threshold by ‘rolling over’ back to the initial value (e.g., from 11111111 to 00000000).

The count values for each word line are stored in a different portion of the bank than the portion which includes the word line. For example, the PRAC counts for the word lines of the first portion 119a are stored along word lines in the second portion 119b. The PRAC counts for the word lines of the second portion 119b are stored along word lines of the first portion 119a. Accordingly, if the row address XADD received along with an activate command ACT specifies the first portion 119a, both row decoders 109a and 109b will activate word lines, and an ACU operation will be performed on the PRAC stored along the word line in the second portion 119b.

The power supply terminals are supplied with power supply potentials VDD and VSS. The power supply potentials VDD and VSS are supplied to an internal voltage generator circuit 124. The internal voltage generator circuit 224 generates various internal potentials VPP, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

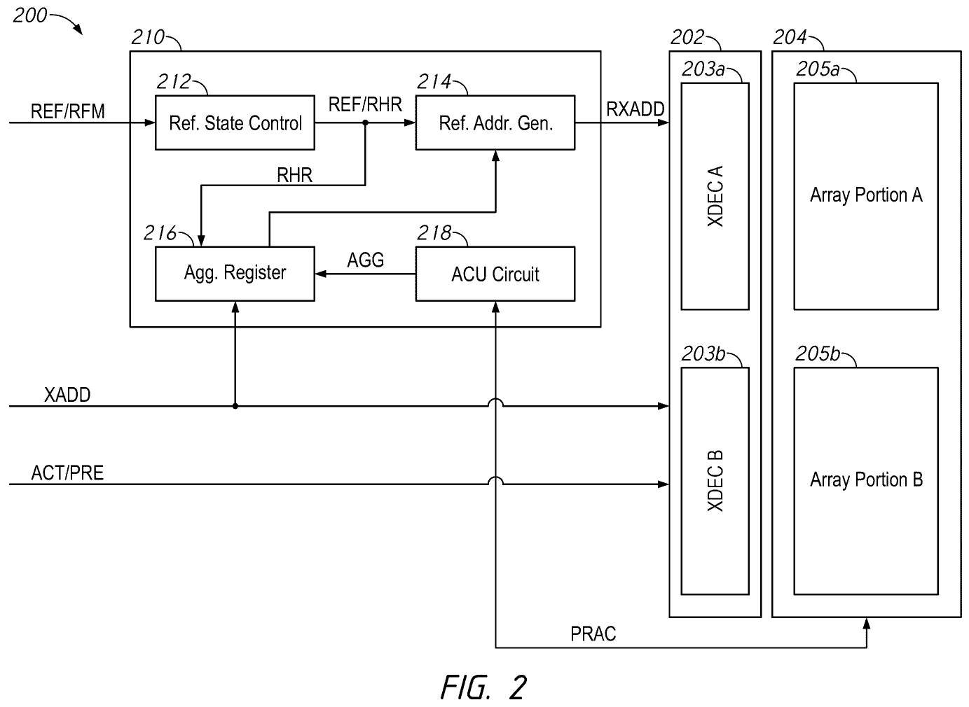

FIG. 2 is a block diagram of bank logic circuits according to some examples of the present disclosure. The bank logic circuits 200 may, in some embodiments, implement a part of a memory device such as 100 of FIG. 1. For example, the bank logic circuits 200 may represent selected circuits in a bank logic region associated with a bank of the memory array. The bank logic circuits 200 of FIG. 2 shows a refresh control circuit 210 (e.g., 116 of FIG. 1), a row decoder 202 (e.g., 108 of FIG. 1) and a memory bank 204 (e.g., 118 of FIG. 1). Certain other circuits which may be part of the bank logic, such as the column decoder, are omitted from the view of FIG. 2.

The refresh control circuit 210 includes a refresh state control circuit 212, a refresh address generator 214, an aggressor register 216 and an ACU logic circuit 218. The refresh state control circuit 212 receives signals such as REF and RFM and determines how many refresh operations should be performed and what types. The refresh address generator circuit 214 generates the refresh address RXADD. The aggressor register 216 stores one or more identified aggressor addresses HitXADD. The ACU logic circuit 218 updates the PRAC count when a word line is accessed and uses the PRAC to determine if the word line is an aggressor. The memory bank 204 is split into a first portion 205a (e.g., 119a of FIG. 1) associated with a first row decoder 203a (e.g., 109a of FIG. 1) and a second portion 205b (e.g., 119b of FIG. 1) associated with a second row decoder 205b (e.g., 109b of FIG. 1).

The refresh state control circuit 212 receives signals such as REF and RFM and determines how many refresh operations to perform and of what type(s). For example refresh state control circuit 212 provides an internal refresh signal IREF to indicate a normal refresh operation and a targeted refresh signal RHR to indicate a targeted refresh operation. In some example implementations, responsive to the refresh signal REF, the refresh state control circuit 212 may perform multiple refresh operations for each time REF or RFM is received. For example, two, four, six, more or fewer refresh operations may be performed. In some example implementations, the refresh state control circuit 212 may perform only normal refresh operations responsive to REF and perform targeted refresh operations responsive to RFM. In some example implementations the refresh state control circuit 212 may perform a mix of normal and targeted refresh operations responsive to REF and perform targeted refresh operations responsive to RFM.

The refresh address generator 214 generates a refresh address RXADD responsive to IREF, RHR, or combinations thereof. For example, responsive to IREF, indicating a normal refresh address, the refresh address generator circuit 214 generates the refresh address RXADD based on sequence logic. For example, the refresh address generator circuit 214 may include a counter, which increments a value to generate a refresh address for normal refresh operations. Responsive to a targeted refresh operation (e.g., the signal RHR) the refresh address generator 214 uses an aggressor address HitXADD to generate one or more refresh addresses. For example, the refresh addresses may represent the word lines which are adjacent to the word line associated with HitXADD. In some embodiments, during a normal refresh operation multiple word lines may be refreshed, while during a targeted refresh operation a single word line may be refreshed. For example, the refresh address generated for a normal refresh operation may be truncated, and every word line which has an address which shares that truncated portion in common may be refreshed by the row decoder 202.

When a word line is accessed, its associated PRAC count is read out to the ACU logic circuit 218. The row address XADD may indicate if it is associated with the first bank portion 205a or the second bank portion 205b. For example, a portion select bit of the row address may have a first state if the row address specifies the first portion 205a or a second state if the row address specifies the second portion 205b. In an example implementation, the bank may be organized such that all of the row addresses which have a most significant bit (MSB) at a logical high are in the first portion 205a and all of the row addresses which have a MSB at a logical low are in the second portion 205b. Accordingly, the most significant bit may act as the portion select bit.

Responsive to an activation command ACT, the row decoder 203 selected by the portion select bit of the row address activates a word line in the respective portion 205 for the access operation. The row decoder 203 not selected by the portion select bit also activates a word line to read out the PRAC. In an example implementation, the count value may be stored along the word line in the opposite portion which matches the address, but has the portion select bit in the opposite state. When the row address selects a word line in the first portion 205a, the associated count value PRAC is read out from a corresponding word line in the second portion 205b. When the row address selects a word line in the second portion 205b, the associated count value PRAC is read out from a corresponding word line in the first portion 205a. In this manner, word lines may be paired between the two portions 205, and each of the paired word lines may store each other's PRAC value. Other ways of organizing the selected word line in one portion and its associated PRAC in the other portion may be used in other example embodiments.

As part of an ACU operation, the ACU logic circuit 218 receives a PRAC value responsive to an activate command ACT. The ACU logic circuit 218 updates the PRAC value, for example by incrementing the PRAC value. If the PRAC value has not crossed a threshold, the updated PRAC value is written back to its original location in the bank 204. If the PRAC value has crossed a threshold, the ACU logic circuit 218 provides an aggressor signal AGG. In some embodiments, responsive to the PRAC value crossing the threshold, the ACU logic circuit 218 resets the PRAC value, for example to an initial value such as 0.

The aggressor register 216 includes a number of ‘slots’ which may be used to store aggressor addresses. For example, each slot may include a number of latch circuits the length of a row address. Responsive to the aggressor signal AGG, the register 216 adds the current row address XADD to the register. The register 216 may act as a FIFO register in some embodiments.

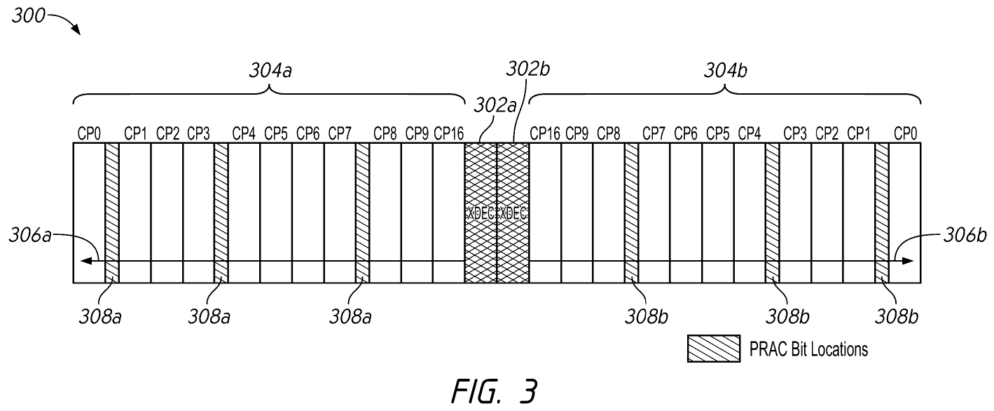

FIG. 3 is a schematic diagram of an example layout of a memory bank according to some embodiments of the present disclosure. The bank 300 may, in some embodiments, implement a bank in the memory array 118 of FIG. 1, the bank 204 of FIG. 2, or combinations thereof. The bank 300 includes a first portion 304a and a second portion 304b (e.g., 119a/b of FIGS. 1 and/or 205a/b of FIG. 2). Each portion is coupled to a respective row decoder 302a or 302b (e.g., 109a/b of FIGS. 1 and/or 203a/b of FIG. 2).

FIG. 3 shows an example layout where the row decoders 302a and 302b are positioned between the two portions 304a and 304b, each coupled to word lines extending from the row decoder through the respective portion 304a or 304b. For example, in the view of FIG. 3, the row decoder 302a is coupled to word lines extending to the left and the row decoder 302b is coupled to word lines extending to the right. Other example layouts may be used in other example embodiments.

Each portion 304a and 304b is divided into a number of column planes CP. Each column plane includes a set of bit lines. During a column command (e.g., a read or write operation) one or more columns in each column plane is selected by a column decoder (e.g., 110 of FIG. 1). For example, the column address may be decoded into a column select signal CS, and the column select signal may select a set of bit lines in each column plane. In an example implementation, there may be 17 column planes per portion 304, and the column select signal may select 8 bit lines per column plane, for a total of 136 bits. Of those, sixteen column planes be used to store data (e.g., 128 bits) may, while the remaining column plane may be used to store error correction bits (e.g., 8 bits). In other example implementations, error correction may be omitted and 16 column planes may be used. Other numbers of column planes, other numbers of word lines per CS signal, or combinations thereof may be used in other example embodiments.

Each portion 304 may include a set of locations 308 set aside to store the PRAC bits. The locations 308 may be distributed throughout the respective portion 304. For example, FIG. 3 shows PRAC bits stored between column planes 0 and 1, between column planes 3 and 4 and between column planes 7 and 8. Other locations and other numbers of locations for the PRAC bits may be used in other example embodiments. The PRAC locations may function in a manner analogous to the column planes, and when a word line is activated, the counter memory cells in the non-selected portion provide bits which together make up the PRAC value.

FIG. 3 shows example word lines 306a and 306b. The word line 306a is in the first portion 304a and coupled to the first row decoder 302a and the word line 306b is in the second portion 304b and is coupled to the second row decoder 302b. In some example implementations, the two word lines 306a and 306b may have row addresses which differ only by the portion select bit. For example, the two word lines 306a and 306b may share a row address except that the row address for the word line 306a has an MSB in a first state and the row address for the word line 306b has an MSB in a second state. During an example access operation, the activation command ACT is received along with a row address which specifies the word line 306a. Responsive to that, first row decoder 302a activates the first word line 306a and the second row decoder 302b activates the word line 306b. The PRAC bits for the word line 306a are read out from the PRAC locations 308b along the second word line 306b.

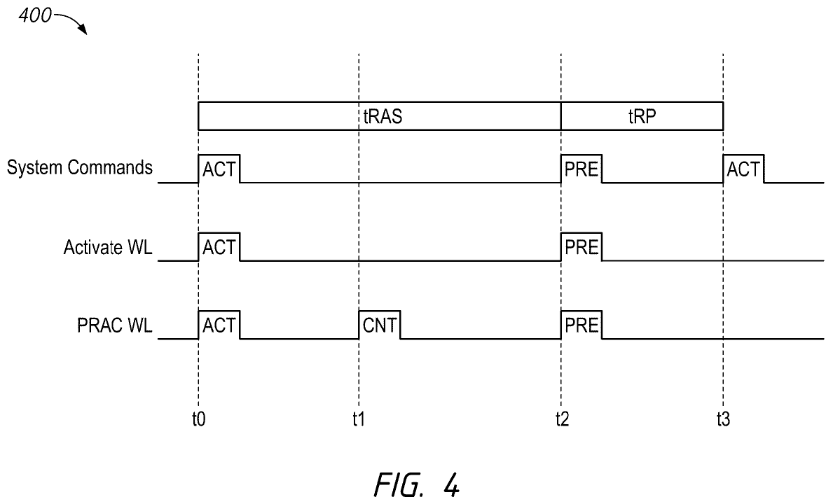

FIG. 4 is an example timing diagram of activation and ACU operations in a memory device according to some embodiments of the present disclosure. The timing diagram 400 may, in some embodiments, represent operations in a memory device such as 100 of FIG. 1. For example, the timing diagram 400 may represent operations in a memory bank such as 204 of FIGS. 2 and/or 300 of FIG. 3.

The timing diagram 400 includes system commands, which represent commands received at C/A terminals of the memory and provided to the row decoders of the specified bank. The timing diagram 400 also includes commands sent to the activated word line (Activate WL) selected by the row address and commands sent to the word line which stores the associated PRAC (PRAC WL). The activated word line may be in a first portion of the memory coupled to a first row decoder and the PRAC WL may be in a second portion of the memory coupled to a second row decoder.

At an initial time t0, the memory receives an activate command ACT. The activate command is provided to the activated WL and to the PRAC WL at the initial time t0. At a first time, an ACU operation, here indicated by CNT is performed on the non-selected word line. At a second time t2, a pre-charge command is received by the memory, and both the activated and PRAC word lines are pre-charged. In this manner the two word lines may be activated at a same time as each other and pre-charged at a same time as each other. The ACU operation happens between t0 and t2. The minimum time between t0 and t2 may be determined by a row activation time tRAS. After the pre-charge command is received at t2, a minimum amount of pre-charge time tRP must elapse before a next activation command can be received. For example, if a next activation command is received as soon as possible at a third time t3, the time between t2 and t3 is tRP. The overall minimum time from activate command to activate command t0 to t3, is tRC. In an example implementation, tRAS (e.g., t0 to t2) may be 36 ns, tRP (e.g., t2 to t3) may be 16 ns, and tRC (e.g., t0 to t3) is 52 ns. Other timings may be used in other example embodiments.

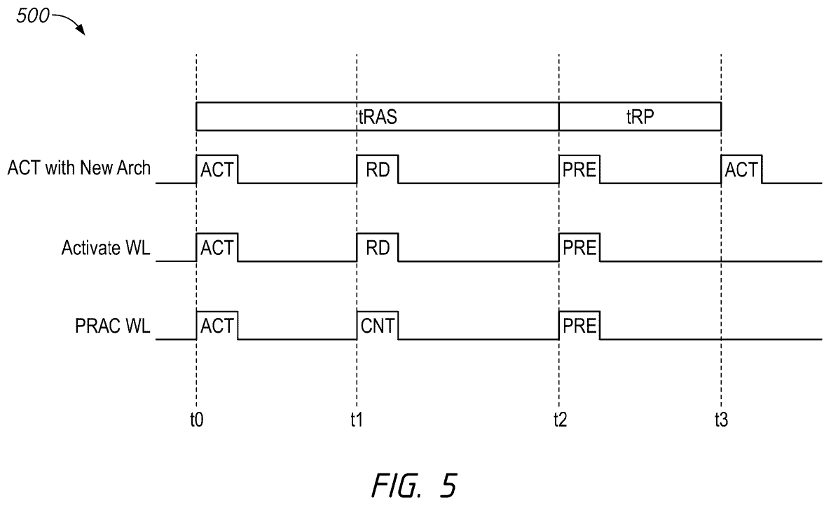

FIG. 5 is an example timing diagram of activation and ACU operations with a column command according to some embodiments of the present disclosure. The timing diagram 500 may generally be similar to the timing diagram 400 of FIG. 4, except that in the timing diagram 500, a column command is received by the memory device. For the sake of brevity, the details already explained with respect to FIG. 4 are not repeated with respect to FIG. 5.

A column command is received at a time between t0 when the activate command ACT is received and t2 when the pre-charge command PRE is received. In the example of FIG. 5, the column command is received at the time t1, when the ACU operation is performed on the PRAC word line. In this example, the column command is performed at a same time as the ACU operation. However, the column command does not have to happen at the same time as the ACU operation.

In this example, the column command is a read operation RD. Since the time tRAS is longer than the time tRCD, which is the minimum time after the activation command before a column command can be performed, one or more column commands can be performed between t0 and t1 without requiring an extension of the time between t0 and t1 beyond tRAS. In other words, one or more column commands may be performed while maintaining the overall timing tRC.

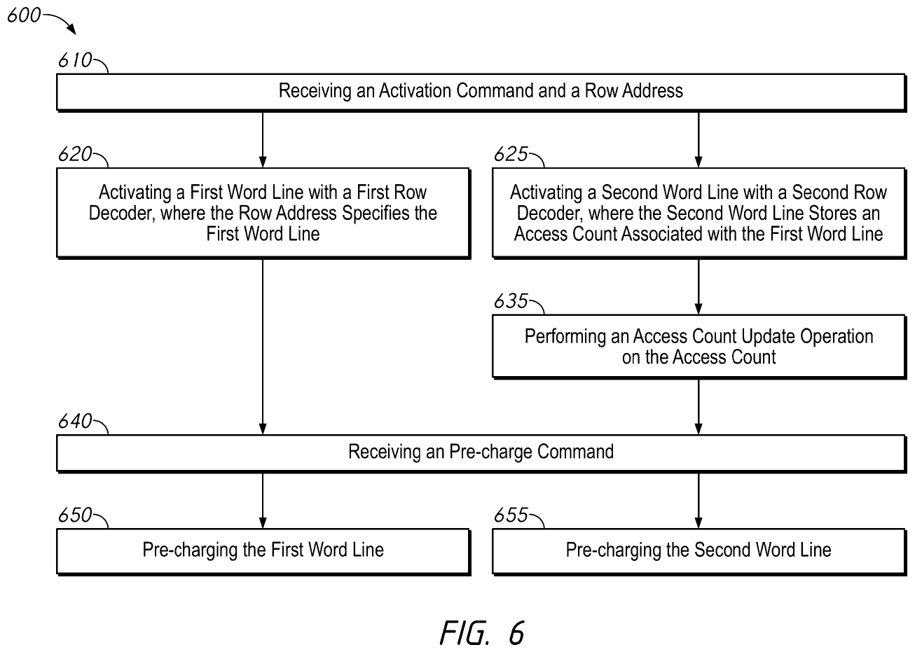

In contrast to the operation of FIG. 6, in a conventional memory device the ACU operation may be performed responsive to the pre-charge command PRE. In order to maintain the specified timings, this may lead to an elongated tRP and a shortened tRAS compared to the timings of FIG. 6. For example, in a conventional device tRAS may be 16 ns and tRP may be 36 ns. Even if a conventional device has have the same tRC as some embodiments of the present disclosure, in a conventional device if a column command is received, the time of the access operation must be extended beyond tRC, since a column command may be not be performed during the shortened tRAS in a conventional device.

FIG. 6 is a flow chart of a method of performing an ACU operation on a count value associated with a word line according to some embodiments of the present disclosure. The method 600 of FIG. 6 may, in some embodiments, be performed by one or more of the apparatuses, systems, or combinations thereof described herein. For example, the method 600 may be performed by the memory device 100 of FIG. 1, the bank logic circuits 200 of FIG. 2, the bank 300 of FIG. 3, or combinations thereof. In some example embodiments, the method 600 may represent operations which occur with timing represented in the timing diagrams 400 of FIG. 4, 500 of FIG. 5, or combinations thereof.

The method 600 may generally begin with box 610, which describes receiving an activation command and a row address. For example, a command address circuit (e.g., 102 of FIG. 1) may receive the activation command row address along command address terminals.

Box 610 may generally be followed by boxes 620 and 630. Box 620 describes activating a first word line with a first row decoder, where the row address specifies the first word line. Box 630 describes activating a second word line with a second row decoder, where the second word line stores an access count associated with the first word line. The first word line and the second word line may be in respective portions (e.g., 119a/b of FIG. 1, 205a/b of FIG. 2, and/or 304a/b of FIG. 3) of the memory array. The method 600 may include determining which portion the row address is associated with based on one or more portion select bits in the row address. For example, the method 600 may include determining that the row address is associated with a first portion based on a most significant bit of the row address being in a first state and determining that the row address is associated with the second portion based on a most significant bit of the row address being in a second state. The method may include activating the first word line and the second word line at approximately the same time responsive to the activation command.

Box 625 may generally be followed by box 635, which describes performing an access count update operation on the access count. For example, box 635 may include reading out the access count to a refresh control circuit (e.g., 116 of FIGS. 1 and/or 210 of FIG. 2), updating the access count and writing the updated access count back to the second word line. The method 600 may include determining if the first word line is an aggressor based on the updated access count. For example, the method may include determining that the first word line is an aggressor if the count value has crossed a threshold. The method 600 may include adding the row address to an aggressor queue responsive to determining that the first word line is an aggressor.

In some embodiments, the method 600 may include receiving one or more column commands while the first word line is active. For example, the method 600 may include receiving a column command and a column address with the command address circuit. Examples of column commands include a read command or a write command. The method 600 may include performing a column operation (e.g., a read or write) on the first word line while the access count update operation is being performed on access count stored along the second word line.

Boxes 620 and 635 may generally be followed by box 640, which describes receiving a pre-charge command. If one or more column commands are received, the pre-charge command is received after the column commands. Box 640 is generally followed by boxes 650 and 655. Box 650 describes pre-charging the first word line and box 655 describes pre-charging the second word line. The first and the second word line may be pre-charged at a same time.

In some embodiments, the first word line may store an access count associated with the second word line. For example, the method 600 may include receiving a second activation command and a second row address which specifies the second word line. The method 600 may include activating the first and the second word lines with the respective first and second row decoders, and performing an access count update operation on the second access count stored along the first word line. In some embodiments, the two word lines may share a row address which is the same except for the one or more portion select bits. For example, they may differ by a state of the most significant bit.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

1. An apparatus comprising:
a command address decoder configured to receive an activate command and a row address;
a first row decoder coupled to a first word line;
a second row decoder coupled to a second word line, wherein the second word line stores an access count value associated with the first word line; and
a refresh control circuit configured to update the access count value when the row address specifies the first word line.

2. The apparatus of claim 1, wherein the first word line stores an second access count value associated with the second word line, and
wherein the refresh control circuit is configured to update the second access count value when the row address specifies the second word line.

3. The apparatus of claim 2, wherein the first row decoder is configured to activate the first word line and the second row decoder is configured to activate the second word line responsive to the activate command when the row address specifies the first or the second word line.

4. The apparatus of claim 1, wherein the first word line is in a first portion of a memory bank and the second word line is in a second portion of the memory bank.

5. The apparatus of claim 4, wherein the first row decoder and the second row decoder are positioned between the first portion and the second portion of the memory bank.

6. The apparatus of claim 1, wherein the command address circuit is further configured to receive a column command after receiving the activate command, the apparatus further comprising:
a column decoder configured to perform a column operation while the refresh control circuit is updating the access count value.

7. The apparatus of claim 1, wherein the command address circuit is further configured to receive a pre-charge command at a time after the receiving the column command, and
wherein the first row decoder is configured pre-charge the first word line responsive to the pre-charge command and the second row decoder is configured to pre-charge the second word line responsive to the pre-charge command.

8. The apparatus of claim 7, wherein the first word line and the second word line are pre-charged at a same time.

9. A method comprising:
receiving an activation command and a row address;
activating a first word line with a first row decoder, wherein the row address specifies the first word line;
activating a second word line with a second row decoder, wherein the second word line stores an access count associated with the first word line; and
performing an access count update on the access count.

10. The method of claim 9, further comprising:
receiving a column command; and
performing a column operation on the first word line while performing the access count update on the access count.

11. The method of claim 9, further comprising:
receiving a pre-charge command;
pre-charging the first word line; and
pre-charging the second word line.

12. The method of claim 11, wherein the pre-charge command is received a time tRAS after receiving the activation command, and wherein performing the column operation does not increase a length of time between the activation and the pre-charge command beyond tRAS.

13. The method of claim 9, further comprising determining if the first word line is an aggressor based on the updated access count.

14. The method of claim 13, further comprising adding the row address to an aggressor queue if the first word line is determined to be an aggressor.

15. The method of claim 9, further comprising:
receiving a second activation command and a second row address;
activating the second word line with the second row decoder, wherein the second row address specifies the second word line;
activating the first word line with the first row decoder, wherein the first word line stores a second access count associated with the second word line; and
performing an access count update on the second access count.

16. An apparatus comprising:
a memory bank comprising a first portion and a second portion;
a command address decoder configured to receive an activate command and a row address which selects one of the first portion or the second portion; and
a refresh control circuit configured to receive an access count from a non-selected one of the first portion or the second portion and perform an access count update operation on the access count.

17. The apparatus of claim 16, wherein the first portion includes a first word line,
wherein the second portion includes a second word line, and
wherein the row address specifies the first word line and the access count associated with the first word line is stored on the second word line.

18. The apparatus of claim 16 further comprising:
a first row decoder coupled to the first portion; and
a second row decoder coupled to the second portion.

19. The apparatus of claim 16, wherein the command address decoder receives a column command,
the apparatus further comprising a column decoder configured to perform a column operation on the selected one of the first portion or the second portion.

20. The apparatus of claim 16, wherein a most significant bit of the row address selects the first portion or the second portion.
